(19) United States
(12) Patent Application Publication
(10) Pub. No.: US 2025/0221170 A1
(43) Pub. Date: Jul. 3, 2025

(54) Light Emitting Display Device

(71) Applicant: LG Display Co., Ltd., Seoul (KR)

(72) Inventors: Dae-Hee Kim, Paju-si (KR); Moon-Soo Kim, Paju-si (KR)

(21) Appl. No.: 18/944,711

(22) Filed: Nov. 12, 2024

(30) Foreign Application Priority Data
Dec. 28, 2023 (KR) 10-2023-0194005

(51) Int. Cl. H10K 59/122; H10K 59/131; H10K 102/00

(52) U.S. Cl. CPC H10K 59/122; H10K 59/131; H10K 2102/341

(57) ABSTRACT

A light emitting display device includes: a substrate including a display region including subpixels and a connection region between adjacent subpixels; a first electrode over first and second divided regions of the subpixel; a bank along a boundary of the subpixel, and including a first opening exposing the first electrode and a second opening corresponding to the connection region; a light emitting layer on the first electrode, and over the first and second divided regions; a protective pattern on the bank around the connection region, and having an upper surface of an irregularly uneven shape; and a second electrode on the light emitting layer, and including first and second electrode patterns in the first and second divided regions, respectively, wherein each of the first and second electrode patterns extends into the connection region while covering the protective pattern, and is connected to a power line in the connection region.

### CROSS REFERENCE TO RELATED APPLICATION

The present application claims the priority benefit of Republic of Korea Patent Application No. 10-2023-0194004 filed on Dec. 28, 2023, which is hereby incorporated by reference in its entirety.

### BACKGROUND

### Field of Technology

The present disclosure relates to a light emitting display device.

### Discussion of the Related Art

Recently, flat panel display devices having excellent characteristics such as thinness, light weight, and low power consumption have been widely developed and applied to various fields.

Among the flat panel display devices, a light emitting display device including a light emitting element such as a light emitting diode is a display device in which charges are injected into a light emitting layer formed between an anode and a cathode to form pairs of electrons and holes, and then the pairs disappear to emit light.

When forming a light emitting element, if a foreign substance is introduced and exists on the anode, the anode and the cathode become short-circuited around the foreign substance, causing a problem that a subpixel becomes darkened.

### SUMMARY

An advantage of the present invention is to provide a light emitting display device that can improve darkening defect of subpixel caused by a short circuit between an anode and a cathode.

Additional features and advantages of the invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, a light emitting display device includes: a substrate including a display region where a plurality of subpixels are arranged and a connection region is arranged between adjacent subpixels; a first electrode formed over first and second divided regions of the subpixel; a bank formed along a boundary of the subpixel, and including a first opening exposing the first electrode and a second opening corresponding to the connection region; a light emitting layer formed on the first electrode, and over the first and second divided regions; a protective pattern on the bank around the connection region, and having an upper surface of an irregularly uneven shape; and a second electrode on the light emitting layer, and including first and second electrode patterns formed in the first and second divided regions, respectively, wherein each of the first and second electrode patterns extends into the connection region while covering the protective pattern, and is connected to a power line in the connection region.

In another embodiment, a light emitting display device includes: a substrate including a display region that includes a plurality of subpixels and a connection region between adjacent subpixels; a first electrode and a light emitting layer formed in the subpixel; a protective pattern at a boundary between each of first and second divided regions of the subpixel and the connection region, and having an upper surface of an uneven shape; and a second electrode on the light emitting layer, and including first and second electrode patterns formed in the first and second divided regions, respectively, wherein each of the first and second electrode patterns extends into the connection region while covering the protective pattern, and is connected to a power line in the connection region.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a plan view schematically illustrating a light emitting display device according to a first embodiment of the present disclosure;

FIG. 2 is a cross-sectional view taken along a line II-II′ of FIG. 1 according to an embodiment of the present disclosure;

FIG. 3 is a cross-sectional view taken along a line III-III′ of FIG. 1 according to an embodiment of the present disclosure;

FIG. 4 is a circuit diagram schematically illustrating a circuit configuration of a subpixel according to a first embodiment of the present disclosure;

FIGS. 5 to 9 are plan views schematically illustrating a method for manufacturing a light emitting display device according to a first embodiment of the present disclosure;

FIGS. 10 to 12 are a plan view, a cross-sectional view, and a circuit diagram, respectively, illustrating a case where a foreign substance exists in a subpixel of a light emitting display device according to a first embodiment of the present disclosure;

FIGS. 13 to 15 are a plan view, a cross-sectional view, and a circuit diagram, respectively, illustrating a case where a first repair process is performed for a subpixel of a light emitting display device to remove a foreign substance and resolve a short circuit between an anode and a cathode according to the first embodiment of the present disclosure;

FIGS. 16 and 17 are a plan view and a circuit diagram, respectively, illustrating a case where a foreign matter is maintained in a subpixel of a light emitting display device according to a first embodiment of the present disclosure;

FIGS. 18 and 19 are a plan view and a circuit diagram, respectively, illustrating a case where a cathode pattern is disconnected by performing a second repair process for a subpixel of a light emitting display device according to a first embodiment of the present disclosure;

FIG. 20 is a plan view schematically illustrating a light emitting display device according to a second embodiment of the present disclosure; and

FIG. 21 is a circuit diagram schematically illustrating a circuit configuration of a subpixel according to a second embodiment of the present disclosure.

### DETAILED DESCRIPTION

Advantages and features of the present invention and methods of achieving them will be apparent with reference to the embodiments described below in detail with the accompanying drawings. However, the present invention is not limited to the embodiments disclosed below, but can be realized in a variety of different forms, and only these embodiments allow the present invention to be complete. The present invention is provided to fully inform the scope of the invention to the skilled in the art of the present disclosure, and the present invention may be defined by the scope of the claims.

The shapes, sizes, proportions, angles, numbers, and the like disclosed in the drawings for explaining the embodiments of the present invention are illustrative, and the present invention is not limited to the illustrated matters. The same reference numerals refer to the same components throughout the description.

Furthermore, in describing the present invention, if it is determined that a detailed description of the related known technology unnecessarily obscure the subject matter of the present invention, the detailed description thereof can be omitted. When ‘comprising’, ‘including’, and ‘having’, and the like are used in this invention, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

In the case of a description of a temporal relationship, for example, when a temporal precedence is described as ‘after’, ‘following’, ‘before’, and the like, cases that are not continuous can be included unless ‘directly’ or ‘immediately’ is used.

In describing components of the present invention, terms such as first, second and the like can be used. These terms are only for distinguishing the components from other components, and an essence, order, order, or number of the components is not limited by the terms.

Respective features of various embodiments of the present invention can be partially or wholly connected to or combined with each other and can be technically interlocked and driven variously, and respective embodiments can be independently implemented from each other or can be implemented together with a related relationship.

Hereinafter, embodiments of the present invention are described in detail with reference to the drawings. Meanwhile, in the following embodiments, the same and like reference numerals are assigned to the same and like components, and detailed descriptions thereof may be omitted.

### First Embodiment

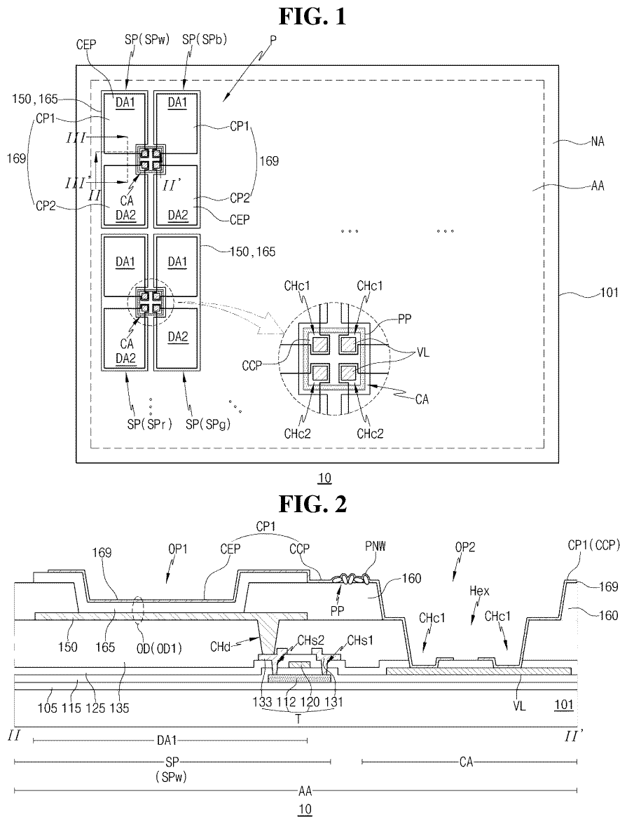

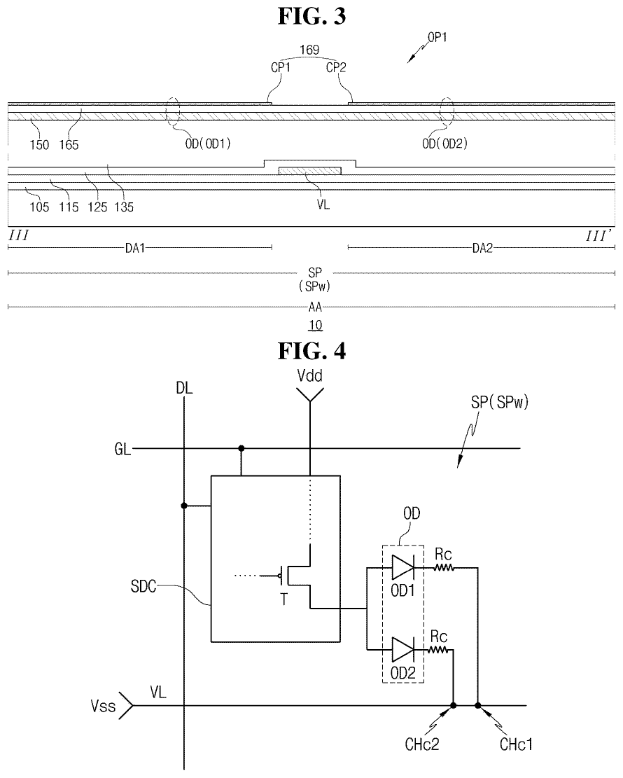

FIG. 1 is a plan view schematically illustrating a light emitting display device according to a first embodiment of the present disclosure. FIG. 2 is a cross-sectional view taken along a line II-II′ of FIG. 1 according to an embodiment of the present disclosure, and FIG. 3 is a cross-sectional view taken along a line III-III′ of FIG. 1 according to an embodiment of the present disclosure. FIG. 4 is a circuit diagram schematically illustrating a circuit configuration of a subpixel according to a first embodiment of the present invention.

Prior to a detailed description, the light emitting display device 10 according to the embodiment of the present invention may include one of all types of display devices that display images with light emitting diodes OD which are self-luminous elements.

In this embodiment, for convenience of explanation, an organic light emitting display device is taken as an example as the light emitting display device 10.

In addition, the light emitting display device 10 may be a top emission type or bottom emission type display device. In this embodiment, for convenience of explanation, a top emission type light emitting display device 10 is taken as an example.

Referring to FIGS. 1 to 4, in the light emitting display device 10 (or light emitting display panel thereof) of the present embodiment, a display region AA for displaying an image and a non-display region NA arranged around the display region AA may be defined.

The display region AA may include a plurality of subpixels SP arranged along a plurality of row lines (or horizontal lines) and a plurality of column lines (or vertical lines) on a substrate 101. Meanwhile, referring to FIG. 4, a plurality of gate lines (or scan lines) GL extending along a row direction (or horizontal direction or first direction) and a plurality of data lines DL extending along a column direction (or vertical direction or second direction) may be formed on the substrate 101. Each subpixel SP may be connected to the corresponding gate line GL and data line DL.

In addition, a power line VL that transmits a low-potential driving voltage (or second driving voltage) Vss may be formed on the substrate 101. The power line VL may extend along the row direction or the column direction. In this embodiment, as illustrated in FIGS. 3 and 4, a case in which the power line VL extends along the row direction is taken as an example. Meanwhile, a power line that transmits a high-potential driving voltage (or first driving voltage) Vdd may be formed on the substrate 101.

The power line VL may be arranged, for example, for each row line. In this case, within the display region AA, the power line VL of each row line may be connected to the subpixels SP arranged on each row line.

The plurality of subpixels SP may include subpixels SP of different colors that constitute a pixel P which is a unit for displaying a color image. In this regard, for example, the plurality of subpixels SP constituting the pixel P may include W, R, G, and B subpixels (or first, second, third, and fourth subpixels) SPw, SPr, SPg, and SPb that respectively display first, second, third, and fourth colors, for example, white (W), red (R), green (G), and blue (B). As another example, the plurality of subpixels SP constituting the pixel P may be configured with R, G, and B subpixels SPr, SPg, and SPb.

In this embodiment, a case in which the pixel P is configured with the W, R, G, B subpixels SPw, SPr, SPg, and SPb is taken as an example. In this case, the light emitting display device 10 may have a high-luminance characteristics by including the W subpixel SPw.

The W, R, G, and B subpixels SPw, SPr, SPg, and SPb may be arranged in various forms. For example, as shown in FIG. 1, the W, R, G, and B subpixels SPw, SPr, SPg, and SPb may be arranged in a quad type in 2 rows by 2 columns. As another example, the W, R, G, and B subpixels SPw, SPr, SPg, and SPb may be arranged in a stripe type.

In this embodiment, regarding the quad type arrangement, for convenience of explanation, a case where the W and B subpixels SPw and SPb are arranged adjacent to each other in a first row which is one of the two rows, and the R and G subpixels SPr and SPg are arranged in a second row which is the other of the two rows is taken as an example. The W, R, G, and B subpixels SPw, SPr, SPg, and SPb may be arranged in a different arrangement form.

In this case, the W and B subpixels SPw and SPb arranged in the first row may be connected to the power line VL arranged in the first row to receive the low-potential driving voltage Vss, and the R and G subpixels SPr and SPg arranged in the second row may be connected to the power line VL arranged in the second row to receive the low-potential driving voltage Vss.

As another example, when the power line VL extends along the column direction, the power line VL may be configured to be commonly connected to the W, R, G, and B subpixels SPw, SPr, SPg, and SPb. In this regard, the power line VL extended along the column direction may extend along a boundary between two adjacent column lines and be commonly connected to the subpixels SP arranged in the two adjacent column lines.

Meanwhile, in the light emitting display device 10 of this embodiment, a cathode 169 may be formed for each subpixel SP. In this case, the subpixel SP may be divided (or separated) into a plurality of regions DA1 and DA2, and the cathode 169 in the subpixel SP may be configured with a plurality of cathode patterns (or electrode patterns) CP1 and CP2 which are divided into the plurality of divided regions DA1 and DA2, and the cathode patterns CP1 and CP2 arranged in the divided regions DA1 and DA2 may be configured to be connected to the power line VL through respective connection contact holes CHc1 and CHc2 provided in a connection region CA.

Accordingly, the light emitting diode OD of each subpixel SP may be configured with a plurality of sub-light emitting diodes OD1 and OD2 respectively having the plurality of cathode patterns CP1 and CP2.

In this embodiment, for convenience of explanation, a case where the subpixel SP includes two divided regions DA1 and DA2 i.e., first and second divided regions DA1 and DA2, and the cathode 169 is configured with two cathode patterns CP1 and CP2 i.e., first and second cathode patterns (or first and second electrode patterns) CP1 and CP2, and first and second connection contact holes CHc1 and CHc2 respectively corresponding to the first and second cathode patterns CP1 and CP2 are formed is taken as an example.

As such, the cathode 169 of the subpixel SP is configured with the divided structure. Accordingly, when a darkening defect is induced by a foreign substance, etc., if a repair process (or a first repair process) that releases a short circuit between the anode 150 and the cathode 169 at a portion where the foreign substance is located is not successful, an additional repair process (or a second repair process) that separates and disconnects a cathode pattern of a divided region where the foreign substance exists can be performed.

Accordingly, only the divided region where the foreign substance is located in the subpixel SP becomes darkened and the remaining divided region can emit light normally, thereby improving darkening defect of the entire subpixel SP, and allowing the subpixel SP to actually perform a normal light emission function.

The structure for improving the darkening defect of this embodiment using the divided structure of the cathode 169 is described in more detail below.

FIGS. 2 and 3 are views schematically illustrating a cross-sectional structure of a light emitting display device according to this embodiment. FIG. 2 illustrates an example of a cross-sectional structure of the first divided region DA1 of the W subpixel SPw and its adjacent connection region CA, and FIG. 3 illustrates an example of a cross-sectional structure of a separate region between the first and second divided regions DA1 and DA2 of the W subpixel SPw. For convenience of explanation, FIG. 2 illustrates one thin film transistor T connected to the light emitting diode OD in the W subpixel SPw. Meanwhile, the cross-sectional structure of FIGS. 2 and 3 may be applied to other subpixels SPr, SPb, and SPg in the same or similar manner.

In addition, FIG. 4 is a diagram schematically illustrating a circuit configuration constituting the W subpixel SPw according to this embodiment. This circuit configuration may be applied to other subpixels SPr, SPb, and SPg in the same or similar manner.

Referring to FIGS. 2 to 4 together with FIG. 1, in each subpixel SP, a subpixel driving circuit SDC including the thin film transistor T, and the light emitting diode OD may be formed on the substrate 101. Meanwhile, in the subpixel driving circuit SDC of each subpixel SP, a plurality of thin film transistors including the thin film transistor T may be formed, and at least one capacitor may be formed.

In more detail, a semiconductor layer 112 may be formed on the substrate 101. The semiconductor layer 112 may be formed of amorphous silicon, polycrystalline silicon, or an oxide semiconductor material, but not limited thereto.

The semiconductor layer 112 may include a central channel region and source and drain regions on both sides thereof.

Meanwhile, a buffer layer 105 may be formed on the substrate 101 and below the semiconductor layer 112.

A gate insulating layer 115 may be formed as an insulating layer made of an insulating material on the semiconductor layer 112. The gate insulating layer 115 may be formed of an inorganic insulating material such as silicon oxide or silicon nitride, but not limited thereto.

A gate electrode 120 formed of a conductive material such as metal may be formed on the gate insulating layer 115 corresponding to the channel region of the semiconductor layer 112.

In addition, the gate line GL connected to a gate electrode of a switching thin film transistor may be formed on the gate insulating layer 115.

Furthermore, the power line VL formed of the same material as the gate electrode 120 and the gate line GL may be formed on the gate insulating layer 115.

An interlayered insulating layer 125 may be formed as an insulating layer made of an insulating material on the gate electrode 120 and the power line VL.

The interlayered insulating layer 125 may be formed of an inorganic insulating material such as silicon oxide or silicon nitride, or an organic insulating material such as benzocyclobutene or photo acrylic, but not limited thereto.

The interlayered insulating layer 125 and the gate insulating layer 115 there below may include a first semiconductor contact hole CHs1 and a second semiconductor contact hole CHs2 that expose the source region and the drain region of the semiconductor layer 112, respectively.

The first semiconductor contact hole CHs1 and the second semiconductor contact hole CHs2 may be positioned on both sides of the gate electrode 120 and spaced apart from the gate electrode 120.

In addition, the interlayered insulating layer 125 may include the first connection contact hole CHc1 and the second connection contact hole CHc2 that expose the power line VL.

The first and second connection contact holes CHc1 and CHc2 may be formed, for example, in the connection region CA formed between the adjacent subpixels SP. In this regard, referring to FIG. 1, the connection region CA may be formed between the W and B subpixels SPw and SPb and between the R and G subpixels SPr and SPg. As such, the connection region CA may be formed in a form surrounded by the subpixels SP on both sides. In the connection region CA, the first and second connection contact holes CHc1 and CHc2 for connection of the first and second cathode patterns CP1 and CP2 of the cathode 169 in each of the subpixels SP on both sides may be arranged.

A source electrode 131 and a drain electrode 133 formed of a conductive material such as a metal may be formed on the interlayered insulating layer 125.

In addition, on the interlayered insulating layer 125, the data line DL that intersects the gate line GL and is connected to a source electrode of the switching thin film transistor may be formed.

Meanwhile, in some cases, the power line VL may be formed in the same process as and of the same material as the source electrode 131, the drain electrode 133, and the data line DL.

The source electrode 131 and the drain electrode 133 may be positioned spaced apart from the gate electrode 120 and contact the source region and the drain region of the semiconductor layer 112 through the first semiconductor contact hole CHs1 and the second semiconductor contact hole CHs2, respectively.

The semiconductor layer 112, the gate electrode 120, the source electrode 131, and the drain electrode 133 configured as described above can form the thin film transistor T.

As another example, the thin film transistor T may have an inverted staggered structure in which the gate electrode 120 is positioned below the semiconductor layer 112, and the source electrode 131 and the drain electrode 133 are positioned over the semiconductor layer 112.

A passivation layer 135 may be formed as an insulating layer made of an insulating material on the source electrode 131, the drain electrode 133 and the data line DL.

The passivation layer 135 may be formed by including at least one of an inorganic insulating material such as silicon oxide or silicon nitride, and an organic insulating material such as benzocyclobutene or photo acrylic, but not limited thereto. The passivation layer 135 may be formed as a single-layered structure or a multi-layered structure.

A drain contact hole CHd exposing the drain electrode 133 may be formed in the passivation layer 135.

In addition, the passivation layer 135 may include an exposure hole Hex exposing the connection region CA (more specifically, exposing the first and second connection contact holes CHc1 and CHc2 of the connection region CA). Accordingly, the first and second connection contact holes CHc1 and CHc2 exposing the power line VL of the connection region CA may be exposed upward through the exposure hole Hex.

On the passivation layer 135, the anode (or first electrode) 150 may be formed for each subpixel SP. In other words, the anode 150 of the subpixel SP may be substantially integrally formed within the subpixel SP and may be formed in a continuous form entirely over the first and second divided regions DA1 and DA2 of the subpixel SP and the separate region between the first and second divided regions DA1 and DA2. The anode 150 may be physically separated and spaced apart from the anode 150 of the neighboring subpixel SP.

The anode 150 may contact the drain electrode 133 through the drain contact hole CHd.

The anode 150 may have high reflective characteristics by including an opaque metal material when the light emitting display device 10 is a top emission type. For example, the anode 150 may include one of silver Ag, aluminum Al, molybdenum Mo, titanium Ti and APC (Al—Pd—Cu) alloy, but not limited thereto.

Meanwhile, the anode 150 may be formed into a multi-layered structure. In this regard, for example, the anode 150 may be formed in a multi-layered structure in which a transparent conductive material (e.g., ITO, IZO, IZTO, etc.) is laminated on and/or below the above-described opaque metal material.

As another example, when the light emitting display device 10 is a bottom emission type, the anode 150 may include a transparent electrode layer and may not have a reflective layer.

A bank 160 may be formed along a boundary of each subpixel SP (or a boundary between the adjacent subpixels SP) on the anode 150.

The bank 160 may be formed to cover an edge of the anode 150 arranged in each subpixel SP.

The bank 160 may be formed of, for example, at least one of an acrylic resin, an epoxy resin, a phenol resin, a polyamide-based resin, a polyimide-based resin, an unsaturated polyester-based resin, a polyphenylene-based resin, a polyphenylene sulfide-based resin, benzocyclobutene, and a photoresist, but not limited thereto.

The bank 160 may have a first opening OP1 that exposes the anode 150 of each subpixel SP. Since light can be emitted from each subpixel SP through the first opening OP1, the first opening OP1 may substantially define a light emission region of each subpixel SP.

The first opening OP1 of the bank 160 may be formed singly and continuously within each subpixel SP. The first opening OP1 may be continuously formed along the first and second divided regions DA1 and DA2 and the separate region between the first and second divided regions DA1 and DA2.

Meanwhile, the bank 160 may have a second opening OP2 corresponding to the connection region CA. In other words, the second opening OP2 of the bank 160 may be formed on the exposure hole Hex of the connection region CA. Through the second opening OP2 and the exposure hole Hex, the first and second connection contact holes CHc1 and CHc2 arranged in the connection region CA may be exposed.

A light emitting layer 165 may be formed along an upper surface of the anode 150 of each subpixel SP and side and upper surfaces of the bank 160. This light emitting layer 165 may be formed for each subpixel SP, similar to the anode 150. In other words, the light emitting layer 165 of the subpixel SP may be substantially formed integrally within the subpixel SP and may be formed in a continuous form entirely over the first and second divided regions DA1 and DA2 of the subpixel SP and the separate region between the first and second divided regions DA1 and DA2. The light emitting layer 165 may be physically separated and spaced from the light emitting layer 165 of the neighboring subpixel SP.

In each subpixel SP, the light emitting layer 165 may be in contact with the anode 150 exposed through the first opening OP1 of the bank 160.

Meanwhile, a protective pattern PP having a rough surface (or rough upper surface) may be formed on the bank 160 along a boundary of the connection region CA (or a boundary between the connection region CA and the subpixel SP). The protective pattern PP may be formed of, for example, a polymer, and may be formed of a fluorine-based polymer according to one embodiment. The fluorine-based polymer has excellent moisture-proof property, and thus can effectively prevent or at least reduce penetration of moisture into the light emitting layer 165.

The protective pattern PP may be formed with a rough upper surface and have a substantially irregular surface. The protective pattern PP may be configured of, for example, a plurality of polymer nanowires PNW.

The polymer nanowires PNW constituting the protective pattern PP may each have a wire shape with a nano size, and the polymer nanowires (PNW) may be arranged irregularly. Accordingly, the protective pattern PP configured of an aggregate of the polymer nanowires PNW may have an irregularly uneven surface shape.

Regarding the formation of the protective pattern PP, for example, by repeatedly performing plasma treatment after coating a fluorine-based polymer, the plurality of polymer nanowires PNW irregularly arranged may be formed. Accordingly, the protective pattern PP configured of an aggregate of the polymer nanowires PNW and having a surface of an irregularly uneven shape may be implemented.

The protective pattern PP may be formed along a periphery of the connection region CA and disposed to surround the connection contact holes CHc1 and CHc2 arranged in the connection region CA. For example, as illustrated in FIG. 1, the protective pattern PP arranged between the adjacent W and B subpixels SPw and SPb may be formed to surround the first and second connection contact holes CHc1 and CHc2 corresponding to (or adjacent to) the W subpixel SPw and the first and second connection contact holes CHc1 and CHc2 corresponding to (or adjacent to) the B subpixel SPb. Likewise, the protective pattern PP arranged between the adjacent R and G subpixels SPr and SPg may be formed to surround the first and second connection contact holes CHc1 and CHc2 corresponding to the R subpixel SPr and the first and second connection contact holes CHc1 and CHc2 corresponding to the G subpixel SPg.

Meanwhile, the protective pattern PP may be formed, for example, to be spaced apart from the light emitting layer 165 on the upper surface of the bank 160. In other words, the protective pattern PP may be formed outside the light emitting layer 165. As another example, the protective pattern PP may be formed on an edge of the light emitting layer 165.

The cathode (or second electrode) 169 may be formed on the light emitting layer 165 and the protective pattern PP. The cathode 169 may be formed for each subpixel SP and may be physically separated and spaced from the cathode 169 of neighboring subpixel SP.

When the light emitting display device 10 is a top emission type, the cathode 169 may include a transparent electrode layer made of a transparent conductive material (e.g., ITO, IZO, IZTO, etc.). As another example, when the light emitting display device 10 is a bottom emission type, the cathode 169 may include a reflective layer formed of metal.

The anode 150, the light emitting layer 165, and the cathode 169 arranged as described above in the first opening OP1 in each subpixel SP may constitute the light emitting diode OD.

The light emitting diode OD emits light from the light emitting layer 165 interposed between the anode 150 and the cathode 169, and the light emitted may travel upward and be output.

For the light emission action, the cathode 169 of each subpixel SP can be connected to the power line VL through the corresponding connection contact holes CHc1 and CHc2 in the connection region CA to receive the low-potential driving voltage Vss.

Meanwhile, in this embodiment, the cathode 169 of each subpixel SP may be divided into the first and second divided regions DA1 and DA2 and configured with the first and second cathode patterns CP1 and CP2 that are physically spaced apart from each other.

As such, since the cathode 169 is divided into the first and second cathode patterns CP1 and CP2, the light emitting diode OD of each subpixel SP may be configured with the first and second sub light emitting diodes OD1 and OD2 respectively equipped with the first and second cathode patterns CP1 and CP2.

The first and second sub light emitting diodes OD1 and OD2 may be configured in a parallel connection form between the thin film transistor T and the power line VL.

The first and second cathode patterns CP1 and CP2 may each have an extension portion (or connection portion) CCP that extends from each of the first and second divided regions DA1 and DA2 to the connection region CA for connection in the connection region CA.

The extension portions CCP of the first and second cathode patterns CP1 and CP2 may be connected to the power line VL through the corresponding (or adjacent) first and second connection contact holes CHc1 and CHc2, respectively. Accordingly, the low-potential driving voltage Vss may be provided to the first and second cathode patterns CP1 and CP2.

Accordingly, each subpixel SP may perform the light emission operation through each of the first and second divided regions DA1 and DA2.

Meanwhile, the first and second cathode patterns CP1 and CP2 may cover the protection pattern PP formed along the periphery of the connection region CA. In other words, the first and second cathode patterns CP1 and CP2 may extend across the protection pattern PP into the connection region CA.

Accordingly, a part of each of the first and second cathode patterns CP1 and CP2 (or a portion of each of the extension portions CCP thereof) that covers the protective pattern PP may have an irregularly uneven shape in cross section along the irregularly uneven shape of the surface of the protection pattern PP.

As such, since the part of the extension portion CCP located on the protective pattern PP has an irregularly uneven shape, this part has a relatively high resistance Rc.

In this regard, portions of the cathode patterns CP1 and CP2 located inside and outside the protective pattern PP have a constant thickness and a smooth shape, while the part of the extension portion CCP covering the protective pattern PP has an uneven shape. Accordingly, the part of the extension portion CCP located on the protective pattern PP has the high resistance Rc due to its morphological characteristics compared to other portions.

In this case, when repairing the darkening of the subpixel SP caused by the foreign substance, if a repair current is applied to the cathode patterns CP1 and CP2, the repair current can be concentrated on a cathode pattern where the foreign substance exists. In this case, the part of the extension portion CCP covering the protective pattern PP is Joule-heated due to the high resistance Rc, so that this part can be melted and removed. Due to this, the extension portion CCP of the cathode pattern is physically separated (i.e., disconnected) on the protective pattern PP, thus the cathode pattern where the foreign substance exists and the power line VL are insulated from each other, thus the low-potential driving voltage Vss is not applied to this cathode pattern, and thus the divided region where the foreign substance exists becomes darkened in a non-luminous state.

Accordingly, since the divided region where the foreign substance does not exist can perform the light emission function normally, it is possible to effectively prevent the entire subpixel SP from being darkened due to the foreign substance.

Meanwhile, in each subpixel SP, the cathode 169 may be configured, for example, such that inside other portion of the cathode 169 except the extension portion CCP is disposed inside the light emitting layer 165. In this regard, in each of the first and second cathode patterns CP1 and CP2 of the cathode 169, side surfaces (or side ends) of an electrode portion CEP which is other portion except the extension portion CCP may be located inside side surfaces (or side ends) of the light emitting layer 165.

As such, by forming the electrode portion CEP of the cathode 169 other than the extension portion CCP within a region of the light emitting layer 165, phenomenon of shrinkage of the light emission region within the subpixel SP can be reduced (or delayed) or prevented. In this regard, an end portion of the light emitting layer 165 may be deteriorated due to penetration of moisture, oxygen, etc., and if the cathode 169 is formed to cover the end of the light emitting layer 165 and have a larger area than the light emitting layer 165, the deterioration progresses inward along the cathode 169, resulting in shrinkage of the light emission region.

However, when the cathode 169 is substantially formed to have a small area without covering the end of the light emitting layer 165 as in this embodiment, the progression of deterioration can be prevented, and thus the phenomenon of shrinkage of the light emission region can be improved.

In addition, in this embodiment, as mentioned above, each of the anode 150 and the light emitting layer 165 can be formed integrally within each subpixel SP having the divided structure and can be formed continuously along the first and second divided regions DA1 and DA2. Accordingly, compared to a structure in which each of the anode 150 and the light emitting layer 165 are divided into the first and second divided regions DA1 and DA2, there is no need to consider tolerance, etc., so that a maximum aperture ratio can be secured in the divided structure.

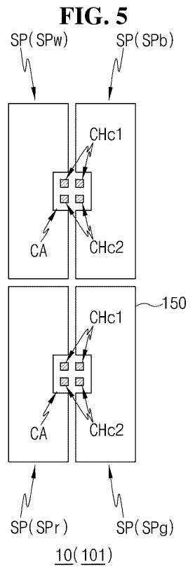

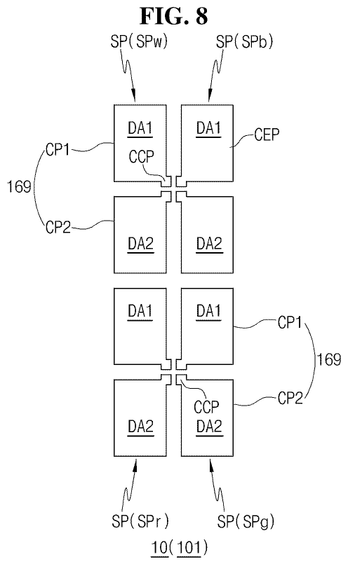

Hereinafter, a method for manufacturing the light emitting display device 10 of this embodiment is described with reference to FIGS. 5 to 9 along with FIGS. 1 to 4. FIGS. 5 to 9 are plan views schematically illustrating a method for manufacturing a light emitting display device according to a first embodiment of the present invention, and shows processes of forming a light emitting diode and a protective pattern. FIG. 8 mainly illustrates the first and second cathode patterns CP1 and CP2 that constitute the cathode 169 for convenience of explanation.

First, referring to FIG. 5, the anode 150 may be formed for each subpixel SP over the substrate 101, on which the passivation layer 135 is formed, by using a photo patterning method. The anodes 150 of the adjacent subpixels SP (e.g., the subpixels SP adjacent in the row direction) may be formed to, for example, surround the connection region CA located between the adjacent subpixels SP.

After the anode 150 is formed, as mentioned above, the bank 160 that covers the edge of the anode 150 may be formed.

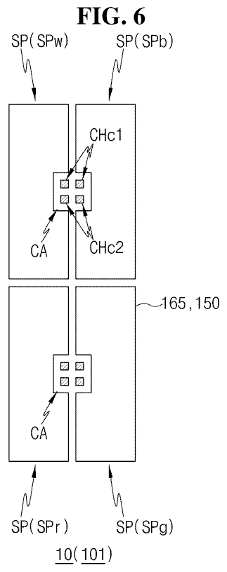

Next, referring to FIG. 6, the light emitting layer 165 may be formed for each subpixel SP on the anode 150 and the bank 160 through a photo patterning method. The light emitting layer 165 of the adjacent subpixels SP (e.g., the subpixels SP adjacent in the row direction) may be formed, for example, to surround the connection region CA located between the adjacent subpixels SP.

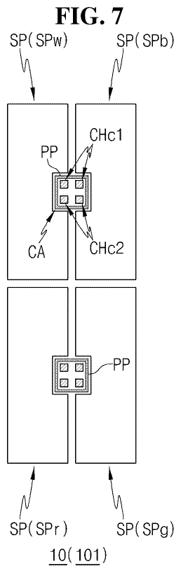

Next, referring to FIG. 7, the protective pattern PP may be formed on the bank 160 along the boundary between the subpixel SP and the connection region CA. The protective pattern PP may be formed of a polymer, and more preferably, may be formed of a fluorine-based polymer.

The protective pattern PP may be configured of the plurality of polymer nanowires PNW, and its upper surface may be formed with a substantially irregularly uneven shape.

Regarding the formation of the protective pattern PP, for example, by coating the fluorine-based polymer and then performing plasma treatment, the plurality of polymer nanowires PNW irregularly arranged may be formed. Accordingly, the protective pattern PP configured of an aggregate of the polymer nanowires PNW and having an irregularly uneven shape on the surface may be formed.

The protective pattern PP may be formed along the periphery of the connection region CA and may be configured to surround the connection contact holes CHc1 and CHc2 arranged in the connection region CA.

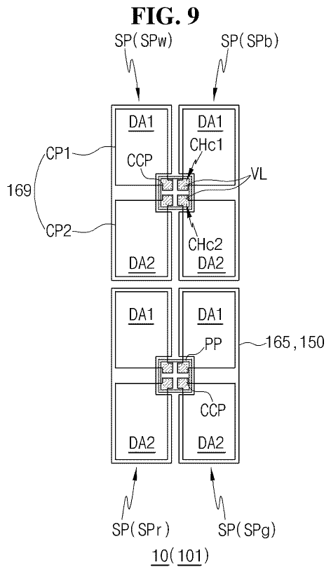

Next, referring to FIGS. 8 and 9, the cathode 169 may be formed for each subpixel SP on the light emitting layer 165, the bank 160, and the protective pattern PP through a photo patterning method. The cathode 169 may be formed in the structure divided into the first and second divided regions DA1 and DA2 within each subpixel SP. Accordingly, the cathode 169 may include the first and second cathode patterns CP1 and CP2 which are disposed in the first and second divided regions DA1 and DA2, respectively, and are spaced apart from each other.

Each of the first and second cathode patterns CP1 and CP2 of the cathode 169 may have the extension portion CCP extending into the connection region CA. The extension portions CCP of the first and second cathode patterns CP1 and CP2 may be connected to the power line VL through the adjacent first and second connection contact holes CHc1 and CHc2, respectively.

Accordingly, in each subpixel SP, the first sub light emitting diode OD1 is formed in the first divided region DA1 where the first cathode pattern CP1 is formed, the second sub light emitting diode OD2 is formed in the second divided region DA2 where the second cathode pattern CP2 is formed, and the light emitting diode OD configured with the first and second sub light emitting diodes OD1 and OD2 connected in parallel to each other may be provided.

The first and second cathode patterns CP1 and CP2 may extend across the protective pattern PP into the connection region CA. Accordingly, the parts of the first and second cathode patterns CP1 and CP2 that cover the protective pattern PP may have an irregularly uneven shape in cross section along the irregularly uneven shape of the surface of the protective pattern PP.

The part of the extension portion CCP, which is the part of each of the cathode patterns CP1 and CP2 having the irregularly uneven shape, has a higher resistance Rc than its surrounding portion due to the uneven shape.

For the subpixel SP formed with the divided structure, in a case where a foreign substance is introduced into the subpixel SP and the anode 150 and the cathode 169 are short-circuited, a method of repairing this is described in detail below.

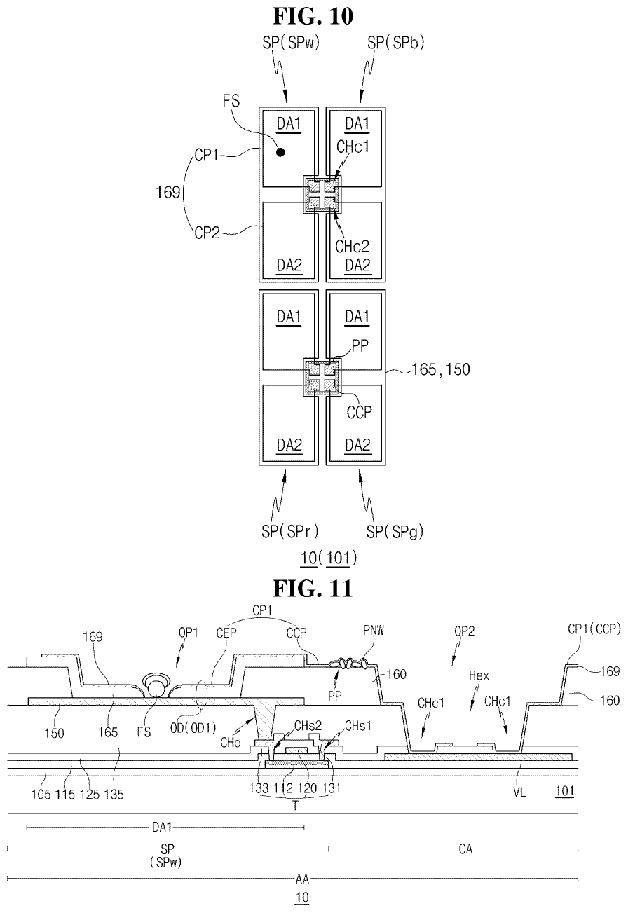

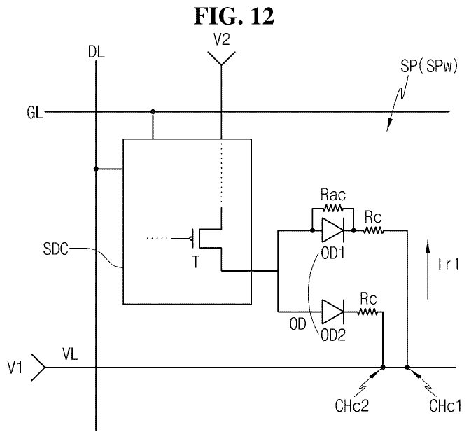

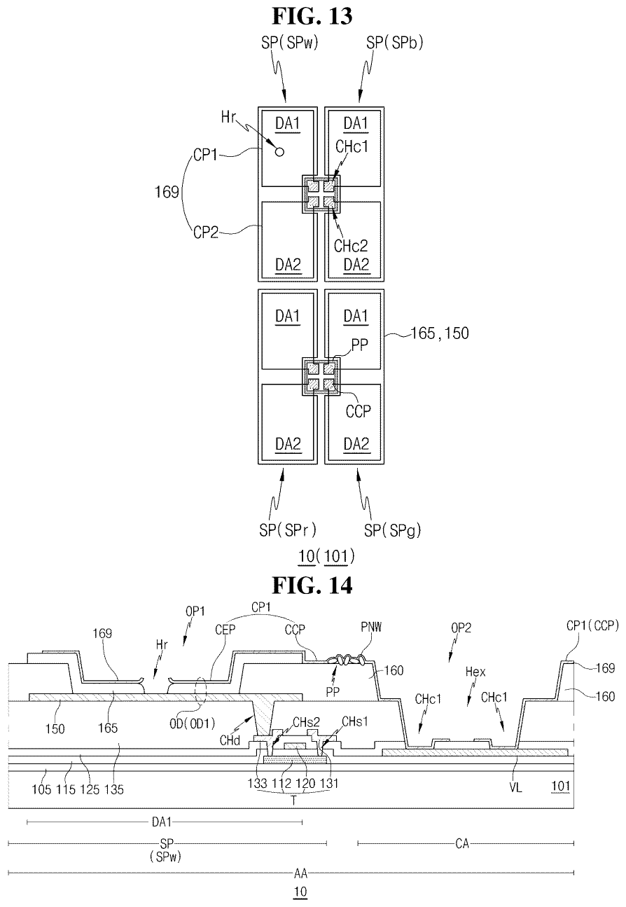

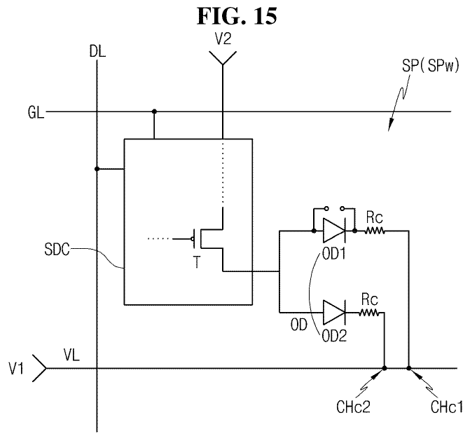

FIGS. 10, 11, and 12 are a plan view, a cross-sectional view, and a circuit diagram, respectively, illustrating a case where a foreign substance exists in a subpixel of a light emitting display device according to a first embodiment of the present disclosure. FIGS. 13, 14, and 15 are a plan view, a cross-sectional view, and a circuit diagram, respectively, illustrating a case where a first repair process (or a first aging process) is performed for a subpixel of a light emitting display device to remove a foreign substance and resolve a short circuit between an anode and a cathode according to the first embodiment of the present disclosure. Meanwhile, in FIGS. 10 to 15, for convenience of explanation, a case where a foreign substance FS is introduced into and removed within the first divided region DA1 of the W subpixel SPw is taken as an example.

Referring to FIGS. 10 to 12, after forming the anode 150, the foreign substance FS may be introduced into the first divided region DA1 of the W subpixel SPw and remain on the anode 150.

Accordingly, when the light emitting layer 165 and the cathode 169 are formed on the anode 150, the light emitting layer 165 and the cathode 169 may be abnormally deposited along the foreign substance FS at a portion where the foreign substance FS exists in the first divided region DA1.

In this case, the light emitting layer 165 and the cathode 169 are deposited on the foreign substance FS, and the light emitting layer 165 and the cathode 169 are not deposited around the foreign substance FS and are disconnected, so that the light emitting layer 165 and the cathode 169 are not formed on the upper surface of the anode 150 where the foreign substance FS exists. An inner end of the cathode 169 may directly contact the anode 150 around the foreign substance FS and be short-circuited with the anode 150.

If the cathode 169 and the anode 150 are short-circuited in this way, most of a light emission current that drives the light emitting diode OD to emit light flows along the short-circuited path of the anode 150 and the cathode 169, so that the entire subpixel SP becomes darkened.

To improve this, a first repair process may be performed to remove the foreign substance FS and the surrounding light emitting layer 165 and cathode 169 in the first divided region DA1.

For example, a first repair current Ir1 may be applied in a reverse direction opposite to a forward direction that is a direction of the current which is for emitting light from the light emitting diode OD. To this end, a first voltage V1 having a relatively high potential may be applied to the power line VL, and a second voltage V2 having a lower potential than that of the first voltage V1 (or a second voltage V2 having the same potential as the first voltage V1 and a lower potential than the first voltage V1 alternately) may be applied to the power line for providing the high-potential driving voltage Vdd to the subpixel SP.

Accordingly, the first repair current Ir1 mostly flows along the short-circuited path of the anode 150 and the cathode 169, and the short-circuited portion between the anode 150 and the cathode 169 is Joule-heated by its resistance Rac.

Therefore, as shown in FIGS. 13 to 15, the short-circuited portion between the anode 150 and the cathode 169, and the foreign substance FS can be melted and removed. By this repair action, a repair hole Hr can be formed at the portion where the foreign substance FS existed. In this case, the inner end of the cathode 169 around the repair hole Hr can have a form that is rolled upward by melting, so that the cathode 169 and the anode 150 can be physically separated.

Accordingly, the short-circuited state between the cathode 169 and the anode 150 is resolved, resulting in a disconnected state. As a result, the darkening defect of the subpixel SP is resolved, allowing normal light emission function to be performed.

Meanwhile, in some cases, the first repair process described above may fail, so that the foreign substance FS may not be removed and the short-circuited state may be maintained, or even if the foreign substance FS is removed, the short-circuited state may be maintained.

In this case, a second repair process (or a second aging process) may be performed to physically disconnect (or separate) the first cathode pattern CP1 of the first divided region DA1.

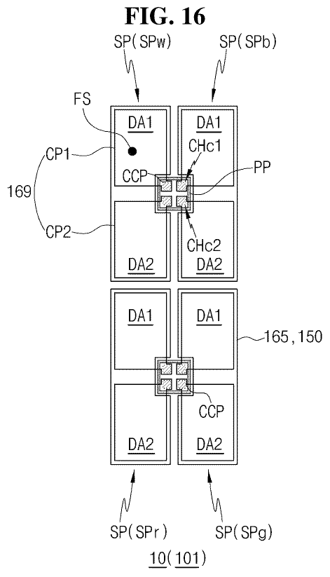

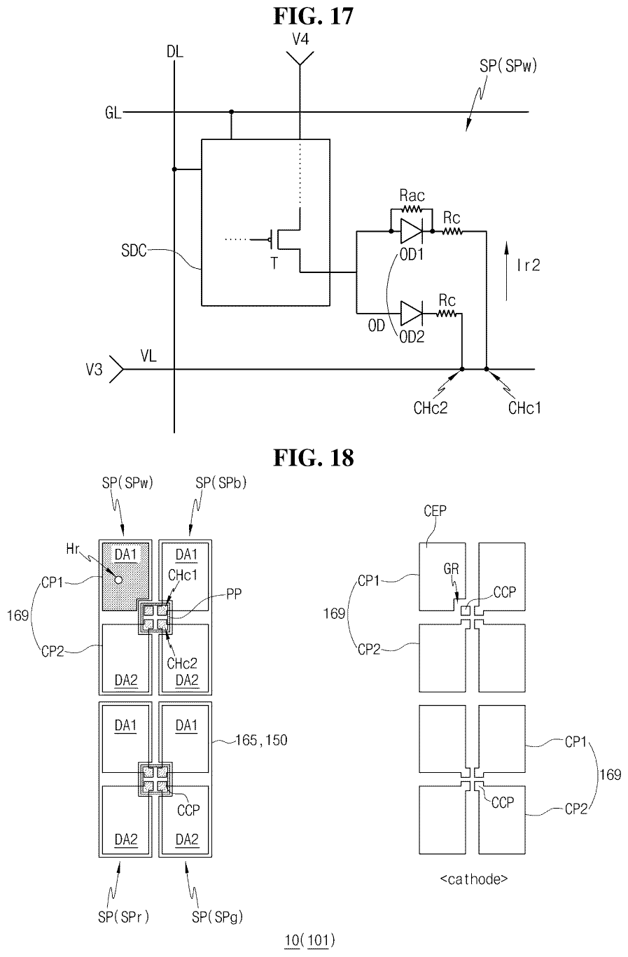

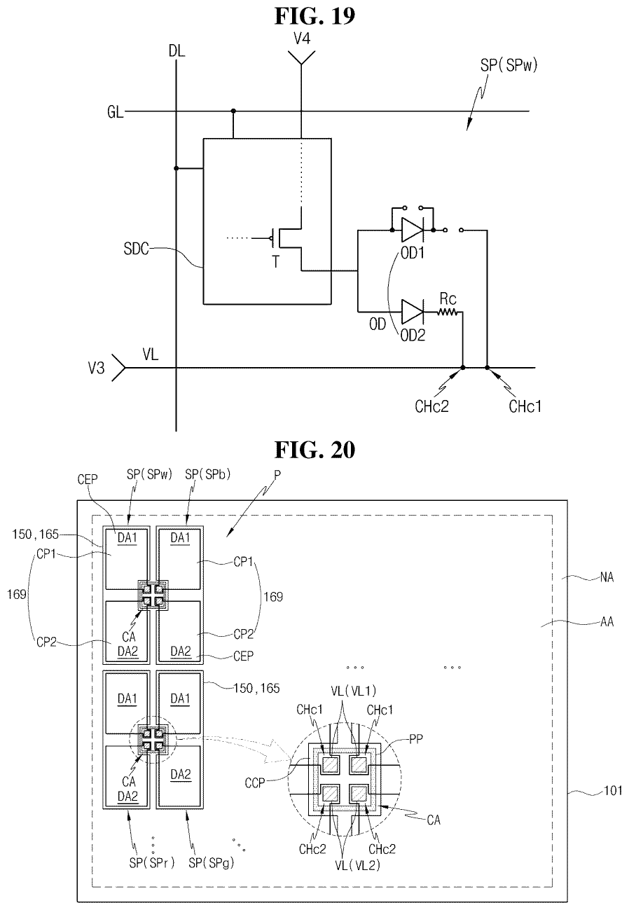

This second repair process is described with reference to FIGS. 16 to 19. FIGS. 16 and 17 are a plan view and a circuit diagram, respectively, illustrating a case where a foreign matter is maintained in a subpixel of a light emitting display device according to a first embodiment of the present disclosure. FIGS. 18 and 19 are a plan view and a circuit diagram, respectively, illustrating a case where a cathode pattern is disconnected by performing a second repair process (or a second aging process) for a subpixel of a light emitting display device according to a first embodiment of the present disclosure.

Referring to FIGS. 16 and 17, the first repair process described above is performed but failed, so that the foreign substance FS is not removed and thus the short-circuited state between the anode 150 and the cathode 169 may be maintained. Or, even if the foreign substance FS is removed, the short-circuited state between the anode 150 and the cathode 169 may be maintained.

In the above case, the entire subpixel SP still has the darkening defect.

To improve this, the second repair process may be performed to physically disconnect the first cathode pattern CP1 of the first divided region DA1 that is in the short-circuited state.

For example, a second repair current Ir2 may be applied in a reverse direction opposite to a forward direction of the current that is for emitting light from the light emitting diode OD. To this end, a third voltage V3 having a relatively high potential may be applied to the power line VL, and a fourth voltage V4 having a lower potential than that of the third voltage V3 (or a fourth voltage V4 having the same potential as the third voltage V3 and a lower potential than the third voltage V3 alternately) may be applied to the power line for providing the high-potential power voltage Vdd to the subpixel SP. A difference between the third voltage V3 and the fourth voltage V4 of the second repair process may be greater than a difference between the first voltage V1 and the second voltage V2 of the first repair process. In other words, the second repair current Ir2 may be higher than the first repair current Ir1.

In this regard, the parts of the cathode patterns CP1 and CP2 formed on the protective pattern PP and having an irregularly uneven shape may be formed so as not to substantially melt when the first repair current Ir1 is applied during the first repair process, but to melt when the second repair current Ir2 higher than the first repair current Ir1 is applied during the second repair process.

As such, the second repair process is set to a harsher condition than the first repair process and can be performed when the first repair process fails.

When the second repair process is performed and the second repair current Ir2 is applied, the second repair current Ir2 mostly flows along the short-circuited path, so that the second repair current Ir2 can be concentrated on the first cathode pattern CP1 of the first divided region DA1 that is in the short-circuited state with the anode 150.

In this case, as shown in FIGS. 18 and 19, the part of the extension portion CCP that is the part of the first cathode pattern CP1 covering the protective pattern PP is Joule-heated due to the high resistance Rc, so that this part can be melted and removed. By this repair action, the first cathode pattern CP1 is physically separated on the protective pattern PP to form a repair separation groove GR, and accordingly, the first cathode pattern CP1 and the power line VL can be insulated from each other. In this case, similar to the above first repair process, an inner end of the first cathode pattern CP1 along a periphery of the repair separation groove GR can have a form that is rolled upward by melting.

Through the second repair process as described above, the first divided region DA1 where the first cathode pattern CP1 that was short-circuited with the anode 150 due to the foreign substance FS is located can be darkened in a non-luminous state.

Therefore, the second divided region DA2 of the subpixel SP where the foreign substance FS does not exist can perform the light emission function normally, so that the entire subpixel SP can be effectively prevented from being darkened due to the short circuit caused by the foreign substance FS.

Meanwhile, through the second repair process as described above, the foreign

substance FS and the short-circuited portion around it can be melted and removed, so that the repair hole Hr can be formed.

### Second Embodiment

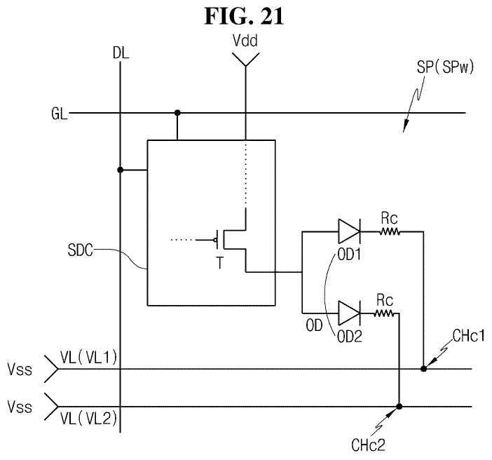

FIG. 20 is a plan view schematically illustrating a light emitting display device according to a second embodiment of the present disclosure. FIG. 21 is a circuit diagram schematically illustrating a circuit configuration of a subpixel according to a second embodiment of the present disclosure.

In the following description, specific explanations of configurations identical to or similar to the first embodiment described above may be omitted.

The light emitting display device 10 of this embodiment may be configured identically and similarly to the first embodiment, except for a structure of a power line VL.

Referring to FIGS. 20 and 21, in the light emitting display device 10 of this embodiment, similar to the first embodiment, each subpixel SP may be formed in a divided structure, and a cathode 169 may be configured with first and second cathode patterns CP1 and CP2 that are arranged in first and second divided regions DA1 and DA2, respectively, and are separated from each other.

Meanwhile, in the light emitting display device 10 of this embodiment, for example, regarding the power line VL that extend along each row line and are connected to the subpixels SP, first and second power lines VL1 and VL2 that are individually connected to the first and second cathode patterns CP1 and CP2 may be provided.

In other words, in each row line, the first power line VL1 that is connected to the first cathode pattern CP1 located in the first divided region DA1 of the subpixel SP through a first connection contact hole CHc1, and the second power line VL2 that is connected to the second cathode pattern CP2 located in the second divided region DA2 of the subpixel SP through a second connection contact hole CHc2 may be arranged.

The first and second power lines VL1 and VL2 may be formed, for example, to extend in parallel along the row direction and be spaced apart from each other.

As such, in this embodiment, the first and second cathode patterns CP1 and CP2 can be configured to be connected to the first and second power lines VL1 and VL2, respectively, instead of being commonly connected to the same power line. Accordingly, current transmission paths from the first and second power lines VL1 and VL2 to the first and second divided regions DA1 and DA2 can be individualized and separated from each other.

Due to this, during the first and second repair processes, the repair currents can be stably provided to the cathode pattern (e.g., the first cathode pattern CP1) that is short-circuited with the anode 150 due to the foreign substance, thereby improving efficiency and success rate of the repair processes.

In addition, since the transmission paths of the light emission currents to the first and second divided regions DA1 and DA2 can also be individualized and separated from each other, signal interference between the first and second divided regions DA1 and DA2 can be reduced and the light emission characteristics of each divided region can be stabilized.

As described above, according to the embodiments of the present disclosure, the cathode of the subpixel can be formed in the divided structure, the divided cathode patterns can be connected to the power line through the corresponding connection contact holes in the connection region, and the protective pattern having a rough surface formed along the periphery of the connection region and having an uneven shape can be formed below the cathode pattern. Accordingly, the part of the cathode pattern located on the protective pattern can have an uneven shape and thus have high resistance.

Accordingly, in the case where the anode and the cathode are short-circuited by a foreign substance and the entire subpixel becomes darkened, when the first repair process for removing the foreign substance and the short-circuited portion around it fails and the short-circuited state is not resolved, the second repair process can be performed to separate and disconnect the cathode pattern of the divided region having the short-circuited state on the protective pattern.

Therefore, the divided region where the foreign substance does not exist can perform the light emission function normally, so that the darkening defect of the entire subpixel due to the short circuit caused by the foreign substance can be effectively prevented.

In addition, the power lines individually connected to the cathode patterns of the subpixel can be provided. Accordingly, the repair current can be stably supplied to the short-circuited cathode pattern, so that the efficiency and success rate of the repair process can be improved.

In addition, the cathode can be formed in a small area without covering the end of the light emitting layer within the subpixel. Accordingly, the deterioration progress into the light emitting layer can be prevented, and the phenomenon of shrinkage of the light emission region can be improved.

In addition, each of the anode and the light emitting layer can be formed integrally within the subpixel and can be formed continuously along the divided regions. Accordingly, compared to the case where each of the anode and the light emitting layer are formed in a divided structure, there is no need to consider tolerance, etc., and the maximum aperture ratio can be secured in the divided structure of the cathode.

In addition, the protective pattern can be formed of a fluorine-based polymer having excellent moisture-proof property. Accordingly, moisture penetration into the light emitting layer can be effectively prevented or at least reduced.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A light emitting display device, comprising:
a substrate including a display region where a plurality of subpixels are arranged and a connection region that is arranged between adjacent subpixels from the plurality of subpixels;
a first electrode over a first divided region and a second divided region of a subpixel from the plurality of subpixels;
a bank along a boundary of the subpixel, the bank including a first opening exposing the first electrode and a second opening corresponding to the connection region;
a light emitting layer on the first electrode and over the first divided region and the second divided region;
a protective pattern on the bank around the connection region, the protective pattern having an upper surface of an irregularly uneven shape; and
a second electrode on the light emitting layer, the second electrode including a first electrode pattern and a second electrode pattern in the first divided region and the second divided region, respectively,
wherein each of the first electrode pattern and the second electrode pattern extends into the connection region while covering the protective pattern and is connected to a power line in the connection region.

2. The light emitting display device of claim 1, wherein the protective pattern includes a fluorine-based polymer.

3. The light emitting display device of claim 2, wherein the protective pattern includes a plurality of nanowires that comprise the fluorine-based polymer and are arranged irregularly.

4. The light emitting display device of claim 1, wherein a resistance of a part of each of the first electrode pattern and the second electrode pattern that cover the protective pattern is higher than a resistance of another part of each of the first electrode pattern and the second electrode pattern.

5. The light emitting display device of claim 1, wherein the protective pattern surrounds the connection region.

6. The light emitting display device of claim 1, wherein a first connection contact hole and a second connection contact hole are in the connection region, and
wherein the first electrode pattern and the second electrode pattern are connected to the power line through the first connection contact hole and the second connection contact hole, respectively.

7. The light emitting display device of claim 1, wherein the first electrode is integral within the subpixel,
wherein the light emitting layer is integral within the subpixel and the first electrode pattern and the second electrode pattern are physically separated from each other within the subpixel.

8. The light emitting display device of claim 1, wherein each of the first electrode pattern and the second electrode pattern is configured such that an electrode portion other than an extension portion, which extends into the connection region while covering the protective pattern, is located inside the light emitting layer.

9. The light emitting display device of claim 1, wherein the power line includes a first power line and a second power line that are connected to the first electrode pattern and the second electrode pattern, respectively, and are spaced apart from each other.

10. The light emitting display device of claim 1, wherein in a case where the first divided region of the subpixel is in a state of darkening defect, the first electrode pattern arranged therein has a disconnected state on the protective pattern.

11. A light emitting display device, comprising:
a substrate including a display region that includes a plurality of subpixels and a connection region between adjacent subpixels from the plurality of subpixels;
a first electrode and a light emitting layer in a subpixel from the plurality of subpixels;
a protective pattern at a boundary between each of a first divided region and a second divided region of the subpixel and the connection region, the protective pattern having an upper surface of an uneven shape; and
a second electrode on the light emitting layer, the second electrode including a first electrode pattern and a second electrode pattern in the first divided region and the second divided region, respectively,
wherein each of the first electrode pattern and the second electrode pattern extends into the connection region while covering the protective pattern and is connected to a power line in the connection region.

12. The light emitting display device of claim 11, wherein the protective pattern includes a plurality of nanowires that comprise a polymer and are arranged irregularly, and
wherein a part of each of the first electrode pattern and the second electrode pattern covering the protective pattern has an uneven shape along the protective pattern.

13. The light emitting display device of claim 11, wherein a resistance of a part of each of the first electrode pattern and the second electrode pattern covering the protective pattern is higher than a resistance of another part of each of the first electrode pattern and the second electrode pattern.

14. The light emitting display device of claim 11, wherein the power line includes a first power line and a second power line that are connected to the first electrode pattern and the second electrode pattern, respectively, and are spaced apart from each other.

15. The light emitting display device of claim 11, wherein in a case where the first divided region of the subpixel is in a state of darkening defect, the first electrode pattern arranged therein has a disconnected state on the protective pattern.
